(19) United States
(12) Patent Application Publication
(10) Pub. No.: US 2024/0146092 A1
(43) Pub. Date: May 2, 2024

(54) CURRENT SENSING CIRCUIT, CORRESPONDING SYSTEM AND VEHICLE

(71) Applicant: STMicroelectronics International N.V., Geneva (CH)

(72) Inventors: Simone BIANCHI, Alessandria (IT); Vanni POLETTO, Milano (IT)

(73) Assignee: STMicroelectronics International N.V., Geneva (CH)

(21) Appl. No.: 18/491,322

(22) Filed: Oct. 20, 2023

(30) Foreign Application Priority Data
Oct. 26, 2022 (IT) 102022000022104

(51) Int. Cl. H02J 7/34; H02M 3/158

(52) U.S. Cl. CPC H02J 7/342; H02M 3/158; H02J 2207/20

(57) ABSTRACT

A circuit for use, e.g., as current sense amplifier in a DC-DC converter in a hybrid vehicle includes a first input node and a second input node, configured to have an input voltage signal applied therebetween, a floating-ground input stage configured to operate between a first supply voltage and a second non-zero supply voltage and to convert into a current signal the input voltage signal applied between the first input node and the second input node. The circuit includes an output stage configured to receive the current signal from the floating-ground input stage and to convert the current signal back to an output voltage signal referred to ground. The output voltage referred to ground is a replica of the input voltage signal applied between the first input node and the second input node.

### BACKGROUND

### Technical Field

The description relates to sensing electric currents.

Embodiments as described herein can apply, for instance, to a current sensing amplifier (CSA) for use in hybrid systems for automotive traction that combine an electric motor with an internal combustion engine.

### Description of the Related Art

Innovative 48V (48 Volt) hybrid systems are currently considered for automotive traction applications that include a compact Lithium-ion 48V battery plus a starter/generator. These systems are complementary to conventional 12V (12 Volt) electric networks that equip most of vehicle on-board systems such as lighting.

The designation HEV (an acronym for Hybrid Electric Vehicle) is currently applied to designate vehicles that combine an electric motor with an internal combustion engine (ICE). In so-called “mild” HEVs, the electric motor provides power assist to the ICE and regenerative braking, with no electric-only mode of propulsion provided.

A DC/DC converter can be provided in order to transfer electric energy between such two batteries, e.g., at 48V and 12V.

A desirable feature of such a DC/DC converter is a current sensing amplifier, CSA exhibiting characteristics such as, by way of example: high input impedance >1MΩ, wide frequency bandwidth >50 MHz, low input offset voltage error <1 mV, low voltage gain error <1%, differential input voltage range=−100 mV to +100 mV, and common mode input voltage range=0V to 24V.

### BRIEF SUMMARY

One or more embodiments contribute to provide an improved circuit suited for use in current sensing and capable of meeting specifications as listed above by way of example.

According to one of more embodiments include a circuit such as a current sensing amplifier, CSA, for instance.

One or more embodiments relate to a corresponding system. A “mild” hybrid system for automotive traction may be exemplary of such a system.

One or more embodiments relate to a corresponding vehicle. A hybrid electric vehicle, combining an electric motor with an internal combustion engine may be exemplary of such a vehicle.

Embodiments as described herein facilitate providing bidirectional DC-DC converters capable of adequately transferring energy between two batteries (e.g., 48V and 12V) in mild hybrid vehicles operating in a multiphase configuration.

Embodiments as described herein can include several (up to six, for instance) power stages or phase subsystems called phase subsystems with each phase subsystem including an inductor and two power transistors that facilitate connecting an inductor alternately to ground and to a first (e.g., 48V) battery in a switch mode.

In embodiments as described herein, each stage can measure (independently of other stages) the current flowing to/from a second (e.g., 12V) battery via a shunt resistor and a differential voltage amplifier operating as a current sense amplifier, CSA.

In embodiments as described herein, a closed loop control is used to regulate the current at the second (e.g., 12V) battery exploiting such current measurement, so that the accuracy of the current measurement directly affects the accuracy of the regulated current.

For instance, in embodiments as described herein, a highest (maximum) tolerated error for the regulated current can be less 1%, with the gain error for the CSA likewise less than 1% and a highest (maximum) input offset that is less than 1 mV.

High-frequency noise, due for example to a parasitic inductance of connections, may be present at the input pins of the CSA.

A low-pass filter (LPF) can be provided at the input pins of the CSA. The CSA input current may lead to some voltage drop at the LPF output, in the case this is made of passive (RC) components. In embodiments as described herein, the CSA input pins have low input current (or a high input impedance) and the current flowing to/from the (e.g., 12V) battery has a wide range of variation with positive and negative values, in a range of −50 A to +50 A per phase. Consequently, considering a typical 2 mΩ shunt resistance, the CSA may operate with a differential input voltage range of, e.g., ±100 mV.

The voltage level on a 12V battery may typically vary in the range from 0V to 24V, considering failure modes (open/short) of the 12V battery. Consequently, an extended battery voltage ranging from 0 to 24V is regarded in embodiments as described herein as a common mode input voltage range in which the CSA should desirably operate in an adequate manner.

In embodiments as described herein, the current control loop is very fast in reacting to transients, and for that reason, components with high-speed performance can be included in the loop. For example, an analog-to-digital (ADC) converter can be used having a pipeline architecture with data rates of 40 Msps together with a digital controller operating at a 40 MHz clock frequency. A CSA as described herein can be included as a component of such a loop, meeting with speed specifications as high as 50 MHz in terms of frequency bandwidth.

In one embodiment, a circuit includes a first input node and a second input node configured to have an input voltage signal applied therebetween. The circuit includes a floating-ground input stage configured to operate between a first supply voltage and a second non-zero supply voltage and to convert into a current signal the input voltage signal applied between the first input node and the second input node. The circuit includes an output stage configured to receive the current signal from the floating-ground input stage and to convert said current signal to an output voltage signal referred to ground, the output voltage referred to ground being a replica of the input voltage signal applied between the first input node and the second input node.

In one embodiment, a system includes a first battery, a second battery, and a DC-DC converter configured to transfer electric charge between the first battery and the second battery via an electric charge transfer line. The DC-DC converter is controlled via a controller configured to receive a sensing signal indicative of an intensity of a current flowing through the electric charge transfer line sensed via a current sensing resistor. The system includes a circuit including a first input node and a second input node coupled to opposite ends of the current sensing resistor to receive an input voltage signal applied therebetween. The circuit is coupled to the controller to provide to the controller via an analog-to-digital converter an output voltage signal referred to ground that is a replica of the input voltage signal. The output voltage signal referred to ground is indicative of the intensity of the current flowing through the electric charge transfer line.

In one embodiment, a method includes receiving an input voltage signal between a first input node of a circuit and a second input node of the circuit and operating a floating-ground input stage of the circuit between a first supply voltage and a second non-zero supply voltage. The method includes converting, with the floating-ground input stage, the input voltage signal to a current signal, receiving, with an output stage, the current signal from the floating-ground input stage, and converting, with the output stage, the current signal to an output voltage signal referred to ground corresponding to a replica of the input voltage signal.

It is otherwise noted that the quantitative data provided in the foregoing are merely exemplary and non-limiting of the embodiments.

### BRIEF DESCRIPTION OF THE SEVERAL VIEWS OF THE DRAWINGS

One or more embodiments will now be described, by way of example only, with reference to the annexed figures, wherein:

FIG. 1 is a block diagram exemplary of a hybrid system for automotive traction equipping a vehicle such as a motor car, according to embodiments of the present description;

FIG. 2 is a circuit diagram of a related phase subsystem including a current sensing feature, according to embodiments of the present description;

FIGS. 3A, 3B and 3C are illustrative of various possible solutions for current sensing, according to embodiments of the present description;

FIG. 4 is a circuit diagram of a (sub)system as illustrated in FIG. 2 including a current sensing feature according to embodiments of the present description; and

FIG. 5 is a circuit diagram of a current sensing circuit, according to embodiments of the present description.

Corresponding numerals and symbols in the different figures generally refer to corresponding parts unless otherwise indicated.

The figures are drawn to clearly illustrate the relevant aspects of the embodiments and are not necessarily drawn to scale.

The edges of features drawn in the figures do not necessarily indicate the termination of the extent of the feature.

Also, for the sake of simplicity and ease of explanation, throughout this description a same designation may apply to a circuit node or line as well as to a signal occurring at that node or line.

### DETAILED DESCRIPTION

In the ensuing description, various specific details are illustrated in order to provide an in-depth understanding of various examples of embodiments according to the description. The embodiments may be obtained without one or more of the specific details, or with other methods, components, materials, etc. In other cases, known structures, materials, or operations are not illustrated or described in detail so that various aspects of the embodiments will not be obscured.

Reference to “an embodiment” or “one embodiment” in the framework of the present description is intended to indicate that a particular configuration, structure, or characteristic described in relation to the embodiment is included in at least one embodiment. Hence, phrases such as “in an embodiment,” “in one embodiment,” or the like, that may be present in various points of the present description do not necessarily refer exactly to one and the same embodiment. Furthermore, particular configurations, structures, or characteristics may be combined in any adequate way in one or more embodiments.

The headings/references used herein are provided merely for convenience and hence do not define the extent of protection or the scope of the embodiments.

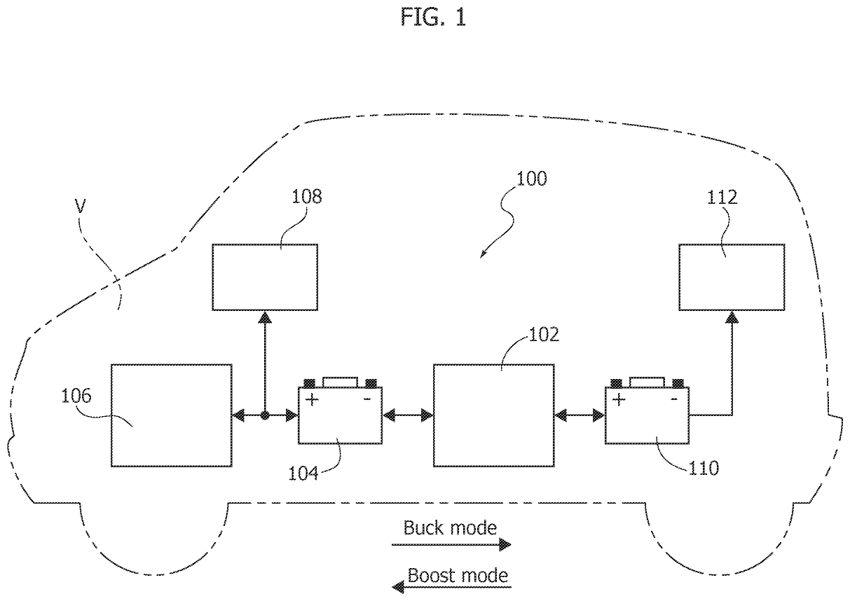

The diagram of FIG. 1 is exemplary of a system including a first battery (here the battery 104) and a second battery (here the battery 110), coupled via a DC/DC converter 102 order to facilitate transfer of electric charge therebetween.

For instance, operation of the converter 102 may be in a buck mode in the direction from the battery 104 (here, a higher voltage battery, e.g., a 48V Li-Ion battery) towards the second battery 110 (here, a lower voltage battery, e.g., a 12V lead battery). Operation in the opposite direction can be in a boost mode. A “buck” or “step-down” voltage regulator is one in which the output voltage is lower than its input voltage. A “boost” or “step-up” voltage regulator is one in which the output voltage is higher than its input voltage.

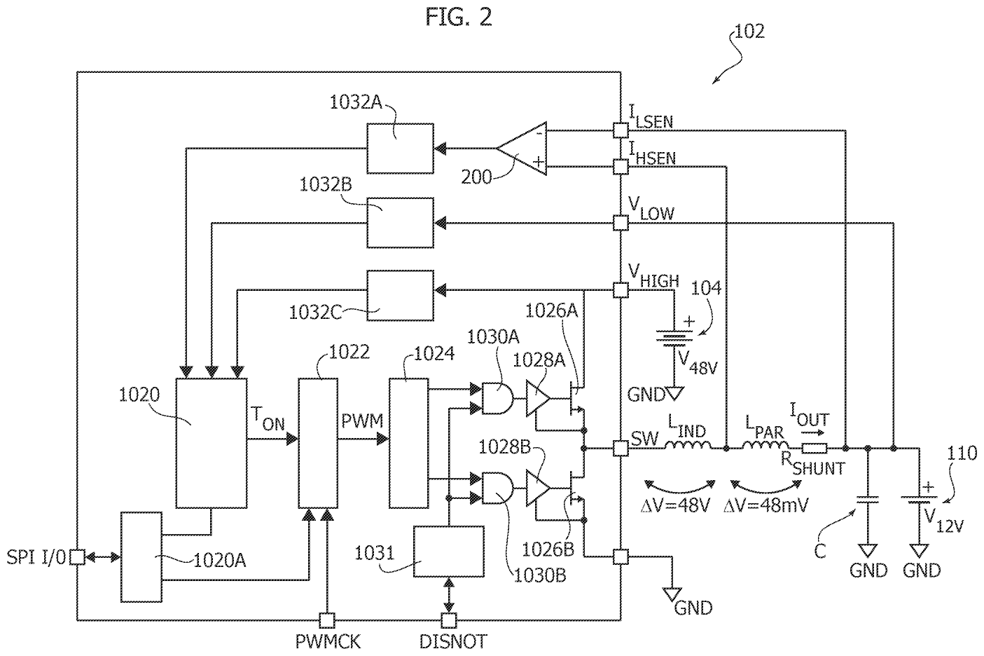

FIG. 2 is an exemplary diagram of a possible implementation of converter such as the converter 120.

Operation of such converter is controlled by a controller 1020 coupled to a controller interface 1020A (e.g., a serial peripheral interface, SPI) receiving a SPI I/O signal.

Reference 1022 denotes a synchronization (Synch) and phase shift circuit block clocked by a clock signal PWMCK and configured to produce, based on a T_{ON} signal from the controller 1020 and under the coordination of the controller interface 1020A, a pulse-width-modulated signal PWM.

The PWM signal is applied (via an anti-cross-conduction circuit block 1024) to two electronic switches (e.g., MOSFET transistors) 1026A (high side, HS) and 1026B (low-side, LS). As illustrated, this occurs via drive stages 1028A, 1028B coupled to control terminals (gates, in the case of field-effect transistors such as MOSFETs) of the high-side and low-side transistors 1026A, 1026B. As illustrated, the stages 1028A, 1028B are in turn driven by the anti-cross-conduction circuit block 1024 that receives the pulse-width-modulated signal PWM from the circuit block 1022 gated via AND gates 1030A, 1030B based on gating signals from a bidirectional disable circuit block 1031 that receives a signal DISNOT.

The high-side and low-side transistors 1026A, 1026B are arranged with the current flow paths therethrough (source-drain, in the case of field-effect transistors such as MOSFETs) cascaded in a current flow line between a node V_{HIGH} to which the first (higher voltage) battery 104 is coupled and ground GND.

The controller 1020 acts on the high-side switch 1026A and the low-side switch 1026B making them alternately conductive and non-conductive so that current flows with respect to the second (lower voltage) battery 110 through an inductor L_{IND} coupled to a node SW located between the high-side switch 1026A and the low-side switch 1026B in the current flow line between the node V_{HIGH} and ground GND.

Coupling of second battery 110 (illustrated as having a parallel capacitance C) to the inductor L_{IND} is via a sensing resistor R_{SHUNT} that produces an “amperometry” signal indicative of (the intensity of) the current I_{OUT} through the inductor L_{IND}.

As illustrated, the sensing resistor R_{SHUNT} has a (parasitic) series inductance L_{PAR}.

The voltage across the sensing resistor R_{SHUNT} (plus the inductance L_{PAR}) is applied as a current sensing signal to the inputs I_{HSEN}, I_{LSEN} of a (differential) current sense amplifier, CSA 200.

Analog-to-digital converters 1032A, 1032B, and 1032C are supplied with the output from the CSA 200, the voltage at a node V_{LOW} coupled to the (second) battery 110 (and the parallel capacitance C) and the voltage at the node V_{HIGH} coupled to the (first) battery 104, so that these signals are applied as (digital) feedback signals to the controller 1020.

Structure and operation of a system as illustrated in FIG. 2 as discussed so far can be regarded as conventional in the art and will not be described in more detail herein.

It will be appreciated that the batteries 104 and 110 (including the capacitance C) plus the inductor L_{IND} and the current sensing resistor R_{SHUNT} are distinct elements from the converter 102.

It will be otherwise appreciated that embodiments as discussed herein are not primarily concerned with operation of the system in general terms; different options can be adopted for that purpose.

It is noted that, whatever the operating option adopted, the current sensing arrangement including the CSA (200 in FIG. 2) plays a significant role in the ultimate performance of the system.

Desirable features for such a CSA include, by way of example: high input impedance >1 MΩ, wide frequency bandwidth >50 MHz, low input offset voltage error <1 mV, low voltage gain error <1%, differential input voltage range=−100 mV to +100 mV, and common mode input voltage range=0V to 24V.

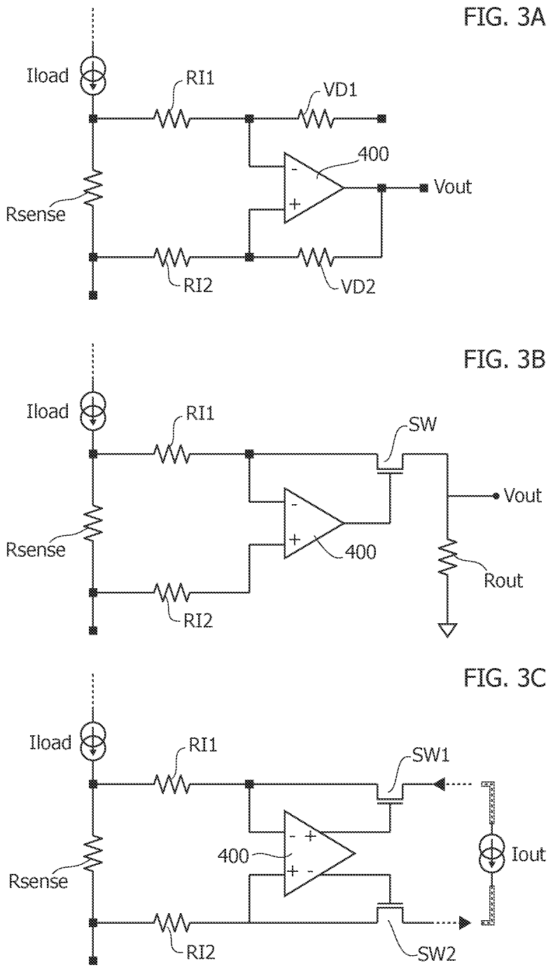

FIGS. 3A to 3C are exemplary of various possible arrangements that can be used in order to sense (measure) the intensity of a current I_{LOAD} flowing through a sensing resistor Rₛₑₙₛₑ.

In the arrangements of FIGS. 3A, 3B, and 3C, a first and a second resistor RI1, RI2 are coupled to the opposite ends of a sensing resistor Rₛₑₙₛₑ to apply a corresponding signal across the inverting and non-inverting inputs of a differential sensing amplifier 400.

In the arrangement of FIG. 3A, the first resistor RI1 is one branch of a voltage divider including a further resistor VD1 as the other branch. The resistor RI2 is likewise one of the branches of a voltage divider having a resistor VD2 providing another branch coupled to an output node Vₒᵤₜ of the sensing amplifier 400.

The arrangement of FIG. 3B includes a pass transistor (a MOSFET transistor, for instance) having its control terminal (gate, in the case of a field-effect transistor such as a MOSFET) driven by the output of the amplifier 400, and the current flow path therethrough (source-drain, in the case of a field-effect transistor such as MOSFET) coupling the resistor RI1 (and the inverting input of the differential amplifier 400) to the output node Vₒᵤₜ of the differential amplifier 400 with an output resistor Rout coupled between the output node Vₒᵤₜ, and ground.

In the arrangement of FIG. 3C, the amplifier 400 is a fully differential amplifier whose outputs (“+” and “−”) drive the control terminals (gates, in the case of field-effect transistors such as MOSFETs) of two transistors acting as pass transistors SW1 and SW2, having the current paths therethrough (source-drain, in the case of field-effect transistors such as MOSFETs) configured to be traversed by an output current Iₒᵤₜ whose intensity minors the intensity of the current I_{load}, thus providing a measure thereof.

The arrangements of FIGS. 3A, 3B and 3C suffer from various drawbacks.

For instance, the arrangement of FIG. 3A exhibits a poor operation when the voltage at both inputs, even if identical, is high, this resulting in a high common mode input voltage.

The arrangement of FIG. 3B exhibits the same drawbacks, in addition to the unavailability of bi-directional input voltage capability.

The arrangement of FIG. 3C somehow palliates the drawbacks discussed in the foregoing at the cost of high input current.

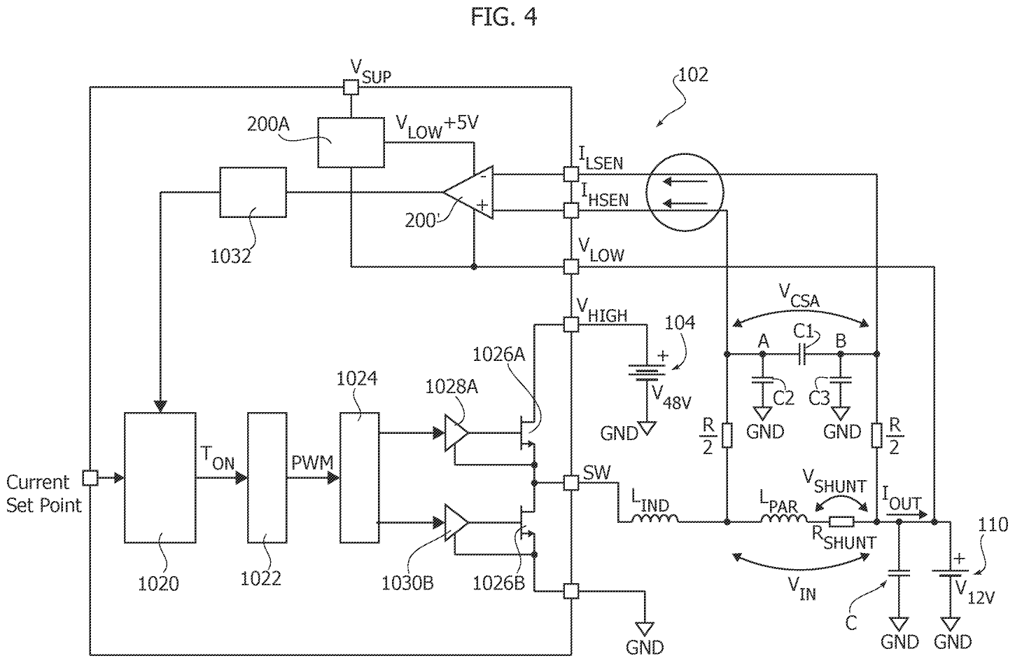

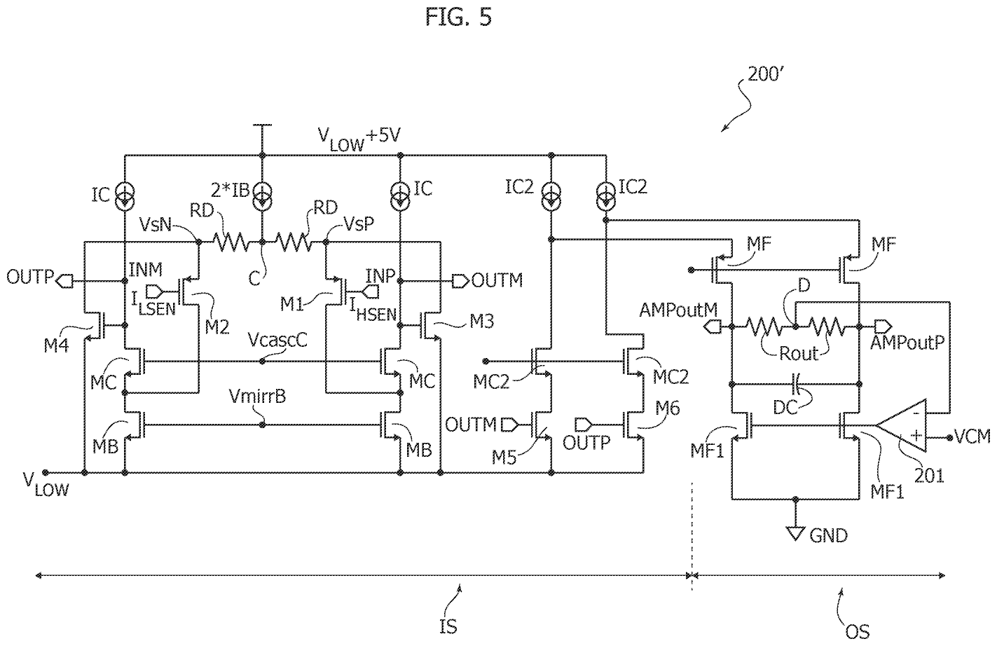

The diagram of FIG. 4 illustrates a system as proposed herein that takes advantage, i.e., of a CSA 200′, having the features discussed in connection with the diagrams of FIGS. 5.

The system illustrated in FIG. 4 also includes a low-pass filter coupled with the current sensing resistor R_{SHUNT}, as further discussed in the following.

In order to facilitate understanding features and advantages of the solution proposed herein, like reference numerals and symbols are used to designate like parts or elements in FIG. 2 and FIG. 4. It will be otherwise appreciated that, while possibly indicated by a same reference numeral/symbol, parts or elements illustrated in FIG. 4 may or may not be implemented like corresponding parts or elements illustrated in FIG. 2.

By way of general reference (and with certain parts or elements illustrated in FIG. 2 not visible in FIG. 4 for simplicity of representation) also the DC/DC converter layout of FIG. 4 includes—like the DC/DC converter layout of FIG. 2—a controller 1020 receiving a Current Set Point signal with a synchronization (Synch) and phase shift circuit block 1022 that produces, based on a T_{ON} signal from the controller 1020, a pulse-width-modulated signal PWM. The PWM signal is applied (via an anti-cross-conduction circuit block 1024) to two electronic switches (e.g., GaN transistors) 1026A (high side, HS) and 1026B (low-side, LS) via drive stages 1028A, 1028B coupled to control terminals (gates, in the case of field-effect transistors such as MOSFETs) of the high-side and low-side transistors 1026A, 1026B.

The high-side and low-side transistors 1026A, 1026B are again arranged with the current flow paths therethrough (source-drain, in the case of field-effect transistors such as MOSFETs) cascaded in a current flow line between a node V_{HIGH} to which the first (higher voltage) battery 104 is coupled and ground GND.

The controller 1020 acts on the high-side switch 1026A and the low-side switch 1026B making them alternately conductive and non-conductive so that current flows with respect to the second (lower voltage) battery 110 through an inductor L_{IND} coupled to a node SW located between the high-side switch 1026A and the low-side switch 1026B in the current flow line between the node V_{HIGH} and ground GND.

Coupling of the second battery 110 (illustrated as having a parallel capacitance C) to the inductor L_{IND} is via a sensing resistor R_{SHUNT} that produces an “amperometry” signal indicative of (the intensity of) the current I_{OUT} through the inductor L_{IND}.

As illustrated, the sensing resistor R_{SHUNT} has a (parasitic) series inductance L_{PAR}.

The voltage across the sensing resistor R_{SHUNT} (plus the inductance L_{PAR}) is applied as a current sensing signal to the inputs I_{HSEN}, I_{LSEN} of a (differential) current sense amplifier, CSA—here designated 200′—that can be implemented according to the circuit diagram of FIG. 5.

The output from the CSA 200′ is applied to analog-to-digital converter circuitry 1032 to be supplied as a (digital) feedback signal to the controller 1020.

Differences between the system illustrated in FIG. 4 and the system illustrated in FIG. 2 comprise primarily the following.

As exemplified in FIG. 5, in the system of FIG. 4 a differential voltage amplifier 200′ is used as the current sense amplifier, CSA, including a “floating” input stage IS supplied with:
the voltage at the node V_{LOW} (essentially the voltage at the battery 110) as a “negative” (lower voltage) supply line, and
a voltage V_{LOW} increased by, e.g., 5V as provided by an associated voltage regulator 200A, as a “positive” (higher voltage) supply line.

The floating input pins of the amplifier 200′ of FIG. 4 have a common mode input voltage ranging from the voltage of the lower voltage supply line V_{LOW} to the voltage of the higher voltage supply line (V_{LOW}+5V, for instance).

A floating ground (FG) arrangement was found to facilitate very accurate ground referenced load current measurements.

It is noted that while 5V is exemplified (also in the figures) as the voltage difference between the lower voltage supply line and the higher voltage supply line of the input stage IS, that value is not mandatory.

The floating voltage regulator 200A is provided for supplying the input stage of the CSA 200′ with the voltages V_{LOW} (lower supply voltage: as illustrated this may be the voltage at the battery 110) and V_{LOW}+5V (regulated higher output voltage) based on a positive supply voltage received at a node V_{SUP} where V_{SUP}>V_{LOW}+5V, for instance.

The differential voltage amplifier 200′, acting as the CSA, has an output stage OS supplied with ground (0V) as a lower “negative” supply and, e.g., 5V as a lower “positive” supply. Such an output stage is able to drive the input pin(s) of a standard ADC converter such as the ADC 1032, having itself the same lower negative supply and lower positive supply of the output stage OS. While not explicitly represented in the diagram of FIG. 5, the supply of the output stage OS might (also) supply an operational amplifier indicated by 201 as discussed later. An adequate value for this (positive) supply can be +5V over ground (GND, assumed to be at 0V).

In the converter 102 of FIG. 4, a low-pass filter arrangement is associated with the shunt resistor R_{SHUNT} for rejecting high-frequency noise: this may be due, e.g., to the parasitic inductance L_{PAR} associated with wiring or connections of the shunt resistor R_{SHUNT}, at printed circuit board (PCB).

As illustrated in FIG. 4, the low-pass filter arrangement includes: a first capacitor C1 between nodes A and B, a second capacitor C2 between the node A and ground, plus a third capacitor C3, between the node B and ground, and resistors of resistance value R/2, between the nodes A and B and opposed ends of the shunt resistor R_{SHUNT}.

As illustrated in FIG. 4, the voltage between the nodes A and B is applied across the nodes I_{HSEN},I_{LSEN} as a (differential) input to the CSA 200′.

Tuning of the RC low-pass filter in question to adequately cancel high-frequency voltage noise may be according to the following criteria.

The low pass transfer function from V_{IN} (the voltage across the shunt resistor R_{SHUNT} plus the parasitic inductance L_{PAR}) to V_{SHUNT} (the voltage across the shunt resistor R_{SHUNT} alone) can be expressed as:

$${H}_{SHUNT} ( s ) = \frac{{V}_{SHUNT} ( s )}{{V}_{IN} ( s )} = \frac{1}{s {τ}_{SHUNT} + 1} ,$$

$$where :$$

$${τ}_{SHUNT} = \frac{{L}_{PAR}}{{R}_{SHUNT}}$$

The low-pass transfer function from V_{IN} to the input voltage V_{CSA} of the CSA 200′ can be expressed as:

$${H}_{CSA} ( s ) = \frac{{V}_{CSA} ( s )}{{V}_{IN} ( s )} = \frac{1}{s {τ}_{CSA} + 1} ,$$

$$where :$$

$${τ}_{CSA} = R {C}_{1}$$

The CSA input voltage V_{CSA}(S) equals the clean shunt resistor output voltage V_{SHUNT}(s) if

V_{CSA}(s)=V_{SHUNT}(s)→H_{CSA}(s)=H_{SHUNT}(s)→τ_{CSA}=τ_{SHUNT}

Hence the tuning criteria for the low pass RC filter is:

$$R {C}_{1} = \frac{{L}_{PAR}}{{R}_{SHUNT}}$$

As illustrated in FIG. 5, the CSA 200′ proposed herein includes a first input node INP and a second input node INM configured to have an input voltage signal applied therebetween.

As illustrated, the CSA 200′ includes a floating-ground input stage IS configured to operate between a first supply voltage (e.g., V_{LOW}+5V) and a second non-zero supply voltage (e.g., V_{LOW}) and to convert into a current signal. As illustrated, the current IC2 is a (fixed) bias current, and the signal current is the one mirrored by the transistors M5 and M6, folded down to the output stage through the transistors MF.

More specifically: the voltage at the pins INP, INM is transferred to the nodes VsP, VsN via the transistors M1, M2; the voltage at the nodes VsP, VsN is transformed into a current through the two resistors RD and the MOS transistors M3 and M4; the current of the transistors M3, M4 is reproduced in the transistors M5, M6; the current through the transistors M5, M6 flows through the transistors MC2, and then through the transistors MF and the two resistors Rout; and the current through the two resistors Rout gives rise to a voltage across (between) the output nodes AMPoutP, AMPoutN.

The two transistors MF facilitate passing the signal from the “floating” environment of the input stage IS to the output stage OS, which is referred to ground.

As illustrated, the CSA 200′ includes an output stage OS configured to receive the current signal from the floating-ground input stage IS and to convert that current signal (back) to an output voltage signal (namely AMPoutP−AMPoutM) referred to ground GND.

That output voltage referred to ground is a replica (and thus a measure) of the input voltage signal applied between the first input node INP and the second input node INM.

A CSA 200′ as illustrated in FIGS. 5 exhibits a high input impedance (virtually no input current) along with a topology suitable for voltage domain changes.

The CSA topology of FIG. 5 also exhibits a high input common mode rejection (a differential signal can be amplified in the presence of a large common-mode input, as is the case for burst noise) together with a bi-directional input voltage capability and a high linearity in voltage-to-current conversion.

The CSA 200′ illustrated in FIG. 5 provides voltage-to-current conversion sharing the advantages discussed in the foregoing in a floating-ground voltage domain (referred to V_{LOW}, namely a non-zero voltage) using standard CMOS transistors that facilitate achieving low-power consumption, a moderately low area occupation and good matching.

More in detail, the CSA 200′ illustrated in FIG. 5 includes an input transistor pair of a first transistor M1 and a second transistor M2 having control terminals (gates in the case of field-effect transistors such as MOSFETs) coupled to the first input node INP and the second input node INM, respectively.

The first M1 and second M2 transistors in the input transistor pair have respective current flow paths therethrough.

The CSA 200′ illustrated in FIG. 5 includes two further transistor pairs (namely M3, M4 and M5, M6).

As illustrated, the transistors M3 and M4 are coupled to the first transistor M1 and to the second transistor M2, respectively, in such a way that a difference of the currents flowing through the transistors M3, M4 (and the difference of the currents flowing through the transistors M5, M6 which, as discussed in the following mirror the currents through the transistors M3 and M4) is a function of the input voltage signal applied between the first input node INP and the second input node INM, thus providing a current signal resulting from conversion to a (differential) current signal of the (differential) input voltage signal applied between the first input node INP and the second input node INM.

As exemplified herein, the first M1 and second M2 transistors have respective current flow paths (source-drain, in the case of field-effect transistors such as MOSFETs) therethrough and first and second degeneration resistors RD are provided having a common node C coupled to the first, higher voltage supply line V_{LOW}+5V to provide a first bias current 2*IB.

In that way, the current I(M1) in the transistor M1 (and the transistor M2) is constant and equal to I(M1)=I(MB)−IC, where I(MB) denotes the current through the transistors MB. Thus the “signal” current in the transistors M1 and M2 is zero.

The (only) transistors that are traversed by a signal current are thus the transistors M3, M4, M5, M6, MC2 (the two of them) and MF (the two of them). The other transistors have a constant current and thus no signal current flowing therethrough.

The first and second degeneration resistors RD are coupled between their common node C and the current flow path through the first transistor M1 and the current flow path through the second transistor M2, respectively.

The input stage IS of the CSA 200′ illustrated in FIG. 5 includes a second transistor pair of a third transistor M3 and a fourth transistor M4 having control terminals (gates, in the case of field-effect transistors such as MOSFETs) coupled to the current flow path (source-drain, in the case of field-effect transistors such as MOSFETs) through the first transistor M1 and to the current flow path through the second transistor M2, respectively.

As illustrated, the first transistor M1 is located between the first degeneration resistor RD and the third transistor M3 while the second transistor M2 is arranged between the second degeneration resistor RD and the fourth transistor M4. In that way, the difference of the currents flowing through the third transistor M3 and through the fourth transistor M4 is a function of the input voltage signal applied between the first input node INP and the second input node INM, and thus represents a current signal resulting from conversion of the input voltage signal applied between the first input node INP and the second input node.

In the exemplary CSA 200′ illustrated in FIG. 5, the third transistor M3 and the fourth transistor M4 have control terminals (gates, in the case of field-effect transistors such as MOSFETs) coupled to current flow lines for (second) bias currents IC between the first supply line V_{LOW}+5V and the second supply line V_{LOW}). As illustrated, these current flow lines IC comprise current source transistors MB, arranged between the second supply line V_{LOW} and the current flow path through the first transistor M1 and the current flow path through the second transistor M2, respectively.

Optionally, the circuit 200′ includes cascode transistors MC cascaded to the current source transistors MB, with the current source transistors MB are arranged between the cascode transistors MC and the second supply line V_{LOW}.

The input stage IS of the exemplary CSA 200′ illustrated in FIG. 5, includes a further transistor pair of a fifth transistor M5 and a sixth transistor M6 that are configured (in a manner known per se to those of skill in the art) to mirror the currents through the third transistor M3 and the fourth transistor M4, respectively.

The (difference of) the currents mirrored via the fifth transistor M5 and a sixth transistor M6 thus again represents (with a possible minor gain) a current signal resulting from conversion into a current signal of the voltage input signal applied between the first input node INP and the second input node INM.

In the exemplary CSA 200′ illustrated in FIG. 5, the fifth transistor M5 and the sixth transistor M6 are arranged in current flow lines for (third) bias currents IC2 between the first supply line V_{LOW}+5V and the second supply line V_{LOW}.

Optionally, the fifth transistor M5 and the sixth transistor M6 have further cascode transistors MC2 cascaded thereto so that the fifth transistor M5 and the sixth transistor M6 are arranged between these further cascode transistors MC2 and the second supply line V_{LOW}.

In a solution as exemplified in FIG. 5, the voltage signal at the amplifier input (INP−INM, namely I_{HSEN}−I_{LSEN}) is thus converted in the input stage IS to a current signal with a high linearity and then folded down in the output stage OS to a low-voltage domain, that is referred to the actual ground GND of the device for further amplification and/or processing.

In a CSA 200′ as exemplified in FIG. 5, the output stage OS includes load resistor circuitry (namely the resistors Rout) coupled (via transistors MF) to the input stage IS to be supplied therefrom the current signal resulting from conversion into a current signal of the voltage input node INP and the second input node INM.

As illustrated, the load resistor circuitry is configured to provide across the load resistors Rout circuitry a (differential) output voltage signal V_{AMPoutP}−V_{AMPoutM} that i) is referred to ground GND, and ii) is a replica (thus a highly linear measure) of the input signal applied between the first input node INP and the second input node INM.

As exemplified herein, the load resistor circuitry includes a first load resistor and a second load resistor Rout coupled between a common node D and respective current flow lines defined by the cascaded current flow lines (source-drain in the case of field-effect transistors such a MOSFETs through two transistors MF, MF1) between the input stage IS and ground GND.

As exemplified herein, the output stage OS of the CSA 200′ optionally includes a voltage regulator 201, MF1 coupled to the common node D between the first and the second load resistors Rout.

The current flow lines through the two transistors MF, MF1 to which the load resistors Rload are coupled are coupled to the current flow lines for the third bias currents IC2 through the fifth transistor M5 and through the sixth transistor M6 (currents IC2), respectively.

As illustrated, the current flow lines through the two transistors MF, MF1 between the input stage IS and ground GND includes current flow paths (source-drain, in the case of field-effect transistors such as MOSFETs) through high-voltage transistors MF, optionally P-type field-effect transistors.

In a CSA 200′ as exemplified in FIG. 5, use of high-voltage MOS components can thus be limited to two high-voltage MOS components for the voltage domain change (in the output stage OS) without affecting the overall amplifier bandwidth.

The current signal is converted again into a voltage signal across two load resistors Rout that provide an amplification as desired.

An amplifier as illustrated in FIG. 5 achieves a clean and precise voltage amplification vs. PVT (process voltage temperature) spread by providing amplifier gain as the ratio between two resistors (RD and Rout) that can be of the same material.

For instance, such a gain can be obtained in two steps: the input voltage signal (as received between two input nodes INP and INM, e.g., the sensing signal I_{HSEN}−I_{LSEN} between the nodes A, B (essentially across the shunt resistor R_{SHUNT}) is converted to a current signal in a floating-ground domain (e.g., IS in FIG. 5), and the current signal is converted again into a voltage signal in a ground-referred domain (e.g., OS in FIG. 5), achieving a desired amplification target.

As an approach to convert a voltage signal into a resistor-based current signal with a high impedance input, a differential pair (e.g., the transistors M1, M2) with resistive degeneration (e.g., RD) is advantageously used.

In such an arrangement, the two currents through the input differential pair (transistors M1, M2) are kept constant and the actual transconductance gain will not depend on the transconductance of the differential pair so that the linearity of the transconductor may be limited by the overdrive voltage of the input transistors.

As illustrated in FIG. 5, the CSA 200′ is intended to operate between a higher-voltage supply line V_{LOW}+(e.g., 5V), as provided by the voltage regulator 200A, and a lower-voltage line V_{LOW} (at a non-zero voltage).

In a MOSFET implementation as exemplified in FIG. 5, a fully differential circuit is provided including an input pair, e.g., the transistors M1 and M2 that receive the input signals INP, INM at their control terminals (gates in the case of field-effect transistors such as MOSFET transistors) with resistive degeneration as provided by resistors RD.

The resistors RD are arranged between nodes VsP and VsN at the sources of the transistors M1, M2, and a common node C that is coupled the supply line V_{LOW}+5V to draw therefrom a (first) bias current 2*IB.

Each of the transistors M1, M2 in the input pair has the current flow path therethrough (e.g., the drain, in the case of field-effect transistors such as MOSFET transistors) coupled on the side opposed to the degeneration resistor RD to an intermediate node between a current source transistor MB and a cascode transistor MC.

The current source transistors MB and cascode transistors MC have the current flow paths therethrough (e.g., source-drain, in the case of field-effect transistors such as MOSFET transistors) cascaded in a current flow line between the upper supply line V_{LOW}+5V and the lower supply line V_{LOW} to be traversed by (second) bias currents IC.

Output transistor M3, M4 are provided having their control terminals (gates, in the case of a field-effect transistors such as a MOSFET transistors) coupled to the current flow lines traversed by the first bias current (e.g., IC) at the drains of the cascode transistors MC.

The output transistors M3, M4 have the current flow paths therethrough (source-drain in the case of a MOSFET transistor) coupled between a respective one of the nodes VsP, VsN, and ground.

Signals OUTP and OUTM as sensed at the (second) bias current lines IC through the transistors MB and MC (that is, at the gates of the output transistors M3 and M4) are applied to the control terminals (gates in the case of field-effect transistors, such as MOSFET transistors) of two further transistors M5 and M6, each cascaded with a respective cascode transistor MC2 in a current flow line between the higher voltage supply line V_{LOW}+5V and the lower voltage supply lines V_{LOW} traversed by a (third) bias current IC2.

An advantageous feature of the input stage structure presented in FIG. 5 lies in that the current flowing into the transistors M1 and M2 can be kept constant being set at the difference between the drain current of the transistors MB and the bias current IC.

As a consequence, the voltage difference V_{INP}−V_{INM} between the voltages at the input nodes INP and INM is transferred to the terminals of the degeneration resistors RD as VsP−VsN.

The body effect of the input pair (transistors M1 and M2) can be cancelled by shorting the body to the source of the transistors.

It is noted that a P-type input pair M1, M2 is optionally chosen for the limited swing of the input signal referred to the lower voltage supply line VLOW. This was found to facilitate a better matching and to provide a lower flicker noise contribution.

In case V_{INM} tends to be higher than V_{INP}, the current increases in the transistor M3 and decreases in the transistor M4, so that the difference is maintained equal to [V_{INP}−V_{INM}]/RD, where RD is the resistance value of the degeneration resistors RD. The value of the (first) bias current, namely IB, can be set considering that the current flowing into the transistors M3 and M4 should desirably be greater than zero for any differential input signal: e.g., I_{M3}=IB−0.5*[V_{INP}−V_{INM}]/RD-(I_{MB}−IC).

The stability of the loops around the transistors M1 and M2 can be facilitated by two small capacitors (not visible for simplicity) connected from the high-impedance nodes OUTP and OUTM, to the lower voltage supply line V_{LOW}.

Once a signal current has been generated, a voltage domain change can be realized by mirroring the currents through the transistors M3 and M4 and folding them down to the ground voltage domain via the transistors M5 and M6.

The transistors M5 and M6 mirror the currents through the transistors M3 and M4 (possibly with amplification).

The two cascode transistors MC2 are optionally added to improve the precision in the mirrored currents.

Finally, two high-voltage transistors MF in the output stage OS are used to fold these currents towards an output branch to provide output signals AMPoutP and AMPoutM so that an output differential voltage signal VAMP_{outP}−VAMP_{outM} becomes available (to be supplied to the ADC converter 1032, for instance) as soon as a differential current flows across two output resistors Rout. The output resistors Rout are coupled each between one of the nodes AMPoutP and AMPoutM and a common node D.

The node D is set to a fixed voltage via the regulator including an error amplifier 201 having an inverting input coupled to the node D, and a non-inverting input set to a reference voltage VCM.

The output of the error amplifier 201 drives the mutually-coupled control terminals (gates, in the case of field-effect transistors such as MOSFET transistors) of the two further transistor MF1 having the current flow paths therethrough (source-drain in the case of field-effect transistors such as MOSFET transistors) cascaded to the current flow path (source-drain, in the case of field-effect transistors such as MOSFET transistors) of the transistors MF.

A capacitor DC can be optionally coupled between the output nodes AMPoutP and AMPoutM with the purpose of limiting the overall amplifier bandwidth if desired.

The overall amplifier voltage gain is thus defined as the ratio of the resistance values of the output and input resistors Rout/RD, multiplied by a mirror ratio between the transistors M3 and M5 (and between the transistors M4 and M6, such mirror ratios being assumed to be equal).

The CSA 200′ illustrated in FIG. 5 lends itself to being used advantageously in a system for possible use in a vehicle V as exemplified in FIG. 1, namely a hybrid motor vehicle equipped with internal combustion engine, ICE traction as well as with electric traction 108 wherein the first battery 104 is coupled to, possibly regenerative, electric traction 108 of the vehicle V. While the second battery 110 supplies on-board equipment such as lighting, advanced driver assistance systems (ADAS), and so on.

In such a system, the first battery 104 may have a first operating voltage and the second battery a second operating voltage, the first operating voltage being optionally higher than the second operating voltage.

For instance, the first battery 104 and the second battery 110 may be a lithium-ion battery and a lead battery, e.g., with operating voltages of 48V and 12V, respectively.

A system as exemplified, e.g., in FIG. 4, includes a DC-DC converter 102 configured to transfer electric charge between the first battery 104 and the second battery 110 via an electric charge transfer line (inductor L_{IND}).

Such a DC-DC converter 102 can be controlled via a controller 1020 configured to receive (e.g., via an ADC converter 1032) a sensing signal indicative of the intensity of the current flowing through the electric charge transfer line L_{IND} as sensed via a current sensing resistor R_{SHUNT}.

A CSA 200′ as exemplified herein can thus be arranged with the first input node INP and the second input node INM coupled across (that is, to opposite ends of) the current sensing resistor R_{SHUNT} to receive the “amperometry” voltage signal I_{HSEN}−I_{LSEN}) applied therebetween.

A CSA 200′ as exemplified herein can be likewise coupled to the controller 1020 to provide to the controller 1020 (optionally via an analog-to-digital converter 1032, in order to facilitate signal processing in digital format), the output voltage signal referred to ground GND across the load resistors Rout between the nodes AMPoutP, AMPoutM.

That (differential) voltage signal is a replica of the input voltage signal applied between the first input node INP and the second input node INM of the CSA 200′ and is thus indicative of the intensity of the current flowing through the electric charge transfer line (inductor L_{IND}).

Advantageously, RC low-pass filtering circuitry (namely the resistors R/2 and the capacitors C1, C2 and C3) is coupled to opposite ends of the current sensing resistor R_{SHUNT} in order to low-pas filter the input voltage signal V_{CSA}, between the nodes I_{HSEN} and I_{LSEN} applied between the first input node INP and the second input node INM to the CSA 200′.

As exemplified herein, the low-pass filtering circuitry includes: first and second resistors R/2 coupled between opposite ends of the sensing resistor R_{SHUNT} and the first input node INP and the second input node INM, respectively, and filtering capacitors C1, C2, C3 coupled between ground GND and a respective one of the first INP and second INM input nodes and/or between the first input node INP and the second input node INM.

Without prejudice to the underlying principles, the details and embodiments may vary, even significantly, with respect to what has been described in the foregoing, by way of example only, without departing from the extent of protection.

The extent of protection is determined by the annexed claims.

A circuit (200′) may be summarized as including a first input node (INP) and a second input node (INM) configured to have an input voltage signal applied therebetween, a floating-ground input stage (IS) configured to operate between a first supply voltage (V_{LOW}+5V) and a second non-zero supply voltage (V_{LOW}) and to convert into a current signal the input voltage signal applied between the first input node (INP) and the second input node (INM), and an output stage (OS) configured to receive the current signal from the floating-ground input stage (IS) and to convert said current signal to an output voltage signal (AMPoutP, AMPoutM) referred to ground (GND), the output voltage referred to ground being a replica of the input voltage signal applied between the first input node (INP) and the second input node (INM).

The floating-ground input stage (IS) may include a first transistor pair of a first transistor (M1) and a second transistor (M2) having control terminals coupled to the first input node (INP) and the second input node (INM), respectively, the first (M1) and the second (M2) transistors having respective current flow paths therethrough, and at least one second transistor pair (M3, M4; M5, M6) coupled to the first transistor (M1) and to the second transistor (M2), respectively, wherein a difference of the currents flowing through the transistors in the at least one second transistor pair (M3, M4; M5, M6) may be a function of the input voltage signal applied between the first input node (INP) and the second input node (INM).

The first transistor (M1) and the second transistor (M2) may include P-type field-effect transistors and/or have bodies shorted to the current flow path therethrough.

The circuit may include first and second degeneration resistors (RD) having a common node (C) coupled to the first supply line (VLOW+5V) to provide a first bias current (2*IB), wherein first and second degeneration resistors (RD) may be coupled between the common node (C) and the current flow path through the first transistor (M1) and the current flow path through the second transistor (M2), respectively, wherein the at least one second transistor pair may include a third transistor (M3) and a fourth transistor (M4) having control terminals coupled to the current flow path through the first transistor (M1) and to the current flow path through the second transistor (M2), respectively, wherein the first transistor (M1) may be arranged between the first degeneration resistor (RD) and the third transistor (M3) while the second transistor (M2) may be arranged between the second degeneration resistor (RD) and the fourth transistor (M4), wherein a difference of the currents flowing through the third transistor (M3) and through the fourth transistor (M4) may be a function of the input voltage signal applied between the first input node (INP) and the second input node (INM).

The third transistor (M3) and the fourth transistor (M4) may have control terminals coupled to current flow lines for second bias currents (IC) between the first supply line (V_{LOW}+5V) and the second supply line (V_{LOW}), said current flow lines for said second bias currents (IC) including current source transistors (MB), arranged between the second supply line (V_{LOW}) and the current flow path through the first transistor (M1) and the current flow path through the second transistor (M2), respectively, the circuit (200′) including cascode transistors (MC) cascaded to said current source transistors (MB) in said current flow lines for second bias currents (IC), wherein said current source transistors (MB) may be arranged between said cascode transistors (MC) and the second supply line (V_{LOW}).

The at least one second transistor pair may include a fifth transistor (M5) and a sixth transistor (M6) arranged in current flow lines for third bias currents (IC2) between the first supply line (VLOW+5V) and the second supply line (VLOW), the fifth transistor (M5) and the sixth transistor (M6) being configured to mirror the currents through the third transistor (M3) and the fourth transistor (M4), respectively, and provide said current signal resulting from conversion of the voltage input signal applied between the first input node (INP) and the second input node (INM).

The fifth transistor (M5) and the sixth transistor (M6) may further include cascode transistors (MC2) cascaded thereto with the fifth transistor (M5) and sixth transistor (M6) arranged between the second supply line (V_{LOW}) and said further cascode transistors (MC2).

The circuit (200′) may include a voltage regulator (200A) configured to produce the first supply voltage (V_{LOW}+5V) from the second supply voltage (V_{LOW}).

The output stage (OS) may include load resistor circuitry (Rout) coupled (M5, M6; MF) to the input stage (IS) to be supplied therefrom the current signal resulting from conversion into a current signal of the voltage input node (INP) and the second input node (INM), wherein the load resistor circuitry (Rout) may be configured to provide across the load resistor circuitry (Rout) the output voltage signal (AMPoutP, AMPoutM) referred to ground (GND) which is a replica of the input signal applied between the first input node (INP) and the second input node (INM).

The load resistor circuitry may include a first load resistor (Rout) and a second load resistor (Rout) coupled between a common node (D) and respective current flow lines (MF, MF1) between the input stage (IS) and ground (GND), the circuit including a voltage regulator (201, MF1) coupled to the common node (D) between the first and the second load resistors (Rout).

The respective current flow lines (MF) may have the first load resistor and the second load resistor (Rload) coupled thereto may be further coupled to the current flow lines for the third bias currents (IC2) through the fifth transistor (M5) and through the sixth transistor (M6), respectively.

The current flow lines (MF, MF1) between the input stage (IS) and ground (GND) may include current flow paths through high-voltage transistors P-type field-effect transistors.

A system may be summarized as including a first battery (104), a second battery (110), a DC-DC converter (102) configured to transfer electric charge between the first battery (104) and the second battery (110) via an electric charge transfer line (L_{IND}), the DC-DC converter (202) controlled via a controller (1020) configured (1032) to receive a sensing signal indicative of the intensity of the current flowing through the electric charge transfer line (L_{IND}) sensed via a current sensing resistor (R_{SHUNT}), wherein the system includes a circuit (200′) according to any of the previous claims, the circuit (200′) having the first input node (INP) and the second input node (INM) coupled to opposite ends of the current sensing resistor (R_{SHUNT}) to receive said input voltage signal (I_{HSEN}, I_{LSEN}) applied therebetween, the circuit (200′) coupled (1032) to the controller (1020) to provide to the controller (1020) via an analog-to-digital converter (1032), the output voltage signal (AMPoutP, AMPoutM) referred to ground (GND) that is a replica of the input voltage signal applied between the first input node (INP) and the second input node (INM) to said circuit (200′), said output voltage signal (AMPoutP, AMPoutM) referred to ground (GND) being indicative of the intensity of the current flowing through the electric charge transfer line (L_{IND}).

The system may include low-pass filtering circuitry (R/2; C1, C2, C3) coupled to opposite ends of the current sensing resistor (R_{SHUNT}), the low-pass filtering circuitry configured to low-pass filter said input voltage signal (V_{CSA}, I_{HSEN}, I_{LSEN}) applied between the first input node (INP) and the second input node (INM) to said circuit (200′), the low-pass filtering circuitry including RC low-pass filtering circuitry.

The low-pass filtering circuitry may include first and second resistors (R/2) coupled between opposite ends of the sensing resistor (R_{SHUNT}) and the first input node (INP) and the second input node (INM), respectively, to said circuit (200′), and filtering capacitors (C1, C2, C3) coupled between ground (GND) and a respective one of the first (INP) and second (INM) input nodes to said circuit (200′) and/or between the first input node (INP) and the second input node (INM) to said circuit (200′).

The first battery (104) may have a first operating voltage and the second battery (110) may have a second operating voltage, the first operating voltage being higher than the second operating voltage.

The first battery (104) and the second battery (110) may be a lithium-ion battery and a lead battery with operating voltages of 48V and 12V, respectively.

A hybrid motor vehicle (V) may be equipped with internal combustion engine traction (118) as well as with electric traction (108) wherein the first battery (104) is coupled to electric traction (108) of the vehicle (V).

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A circuit, comprising:
a first input node and a second input node;
a floating-ground input stage configured to operate between a first supply voltage and a second non-zero supply voltage and to convert an input voltage applied between the first input node and the second input node into a current signal the input voltage signal applied between the first input node and the second input node; and
an output stage configured to receive the current signal from the floating-ground input stage and to convert said current signal to an output voltage signal referred to ground, the output voltage referred to ground being a replica of the input voltage signal applied between the first input node and the second input node.

2. The circuit of claim 1, wherein the floating-ground input stage includes:
a first transistor pair of a first transistor and a second transistor having control terminals coupled to the first input node and the second input node, respectively, the first and the second transistors having respective current flow paths therethrough, and
at least one second transistor pair coupled to the first transistor and to the second transistor, respectively, wherein a difference of the currents flowing through the transistors in the at least one second transistor pair is a function of the input voltage signal applied between the first input node and the second input node.

3. The circuit of claim 2, wherein the first transistor and the second transistor include P-type field-effect transistors and/or have bodies shorted to the current flow path therethrough.

4. The circuit of claim 2, comprising first and second degeneration resistors having a common node coupled to the first supply line to provide a first bias current, wherein first and second degeneration resistors are coupled between the common node and the current flow path through the first transistor and the current flow path through the second transistor, respectively,
wherein the at least one second transistor pair includes a third transistor and a fourth transistor having control terminals coupled to the current flow path through the first transistor and to the current flow path through the second transistor, respectively, wherein the first transistor is arranged between the first degeneration resistor and the third transistor while the second transistor is arranged between the second degeneration resistor and the fourth transistor, wherein a difference of the currents flowing through the third transistor and through the fourth transistor is a function of the input voltage signal applied between the first input node and the second input node.

5. The circuit of claim 4, wherein the third transistor and the fourth transistor have control terminals coupled to current flow lines for second bias currents between the first supply line and the second supply line, said current flow lines for said second bias currents including current source transistors, arranged between the second supply line and the current flow path through the first transistor and the current flow path through the second transistor, respectively, the circuit including cascode transistors cascaded to said current source transistors in said current flow lines for second bias currents, wherein said current source transistors are arranged between said cascode transistors and the second supply line.

6. The circuit of claim 4, wherein the at least one second transistor pair includes a fifth transistor and a sixth transistor arranged in current flow lines for third bias currents between the first supply line and the second supply line, the fifth transistor and the sixth transistor being configured to mirror the currents through the third transistor and the fourth transistor, respectively, and provide said current signal resulting from conversion of the voltage input signal applied between the first input node and the second input node.

7. The circuit of claim 6, wherein the fifth transistor and the sixth transistor have further cascode transistors cascaded thereto with the fifth transistor and sixth transistor arranged between the second supply line and said further cascode transistors.

8. The circuit of claim 1, comprising a voltage regulator configured to produce the first supply voltage from the second supply voltage.

9. The circuit of claim 1, wherein the output stage includes load resistor circuitry coupled to the input stage to be supplied therefrom the current signal resulting from conversion into a current signal of the voltage input node and the second input node, wherein the load resistor circuitry is configured to provide across the load resistor circuitry the output voltage signal referred to ground which is a replica of the input signal applied between the first input node and the second input node.

10. The circuit of claim 9, wherein the load resistor circuitry includes a first load resistor and a second load resistor coupled between a common node and respective current flow lines between the input stage and ground, the circuit comprising a voltage regulator coupled to the common node between the first and the second load resistors.

11. The circuit of claim 6, wherein the respective current flow lines having the first load resistor and the second load resistor coupled thereto are further coupled to the current flow lines for the third bias currents through the fifth transistor and through the sixth transistor, respectively.

12. The circuit of claim 10, wherein the current flow lines between the input stage and ground includes current flow paths through high-voltage P-type field-effect transistors.

13. A system, comprising:
a first battery;
a second battery;
a DC-DC converter configured to transfer electric charge between the first battery and the second battery via an electric charge transfer line, the DC-DC converter controlled via a controller configured to receive a sensing signal indicative of an intensity of a current flowing through the electric charge transfer line sensed via a current sensing resistor; and
a circuit including a first input node and a second input node coupled to opposite ends of the current sensing resistor, the circuit coupled to the controller to provide to the controller via an analog-to-digital converter an output voltage signal referred to ground that is a replica of an input voltage signal applied between the first input node and the second input node, said output voltage signal referred to ground being indicative of the intensity of the current flowing through the electric charge transfer line.

14. The system of claim 13, comprising RC low-pass filtering circuitry coupled to opposite ends of the current sensing resistor, the RC low-pass filtering circuitry configured to filter said input voltage signal applied between the first input node and the second input node to said circuit.

15. The system of claim 14, wherein the RC low-pass filtering circuitry includes:
first and second resistors coupled between opposite ends of the current sensing resistor and the first input node and the second input node, respectively, to said circuit; and
filtering capacitors coupled between ground and a respective one of the first and second input nodes to said circuit and/or between the first input node and the second input node to said circuit.

16. The system of claim 14, wherein the first battery has a first operating voltage and the second battery has a second operating voltage, the first operating voltage being higher than the second operating voltage.

17. The system of claim 14, wherein the first battery and the second battery are a lithium-ion battery and a lead battery with operating voltages of 48V and 12V, respectively.

18. A method, comprising:
receiving an input voltage signal between a first input node of a circuit and a second input node of the circuit;
operating a floating-ground input stage of the circuit between a first supply voltage and a second non-zero supply voltage;
converting, with the floating-ground input stage, the input voltage signal to a current signal;
receiving, with an output stage, the current signal from the floating-ground input stage; and
converting, with the output stage, the current signal to an output voltage signal referred to ground corresponding to a replica of the input voltage signal.

19. The method of claim 18, wherein the floating-ground input stage includes:
a first transistor pair of a first transistor and a second transistor having control terminals coupled to the first input node and the second input node, respectively, the first and the second transistors having respective current flow paths therethrough, and
at least one second transistor pair coupled to the first transistor and to the second transistor, respectively, wherein a difference of the currents flowing through the transistors in the at least one second transistor pair is a function of the input voltage signal applied between the first input node and the second input node.

20. The method of claim 19, wherein the first transistor and the second transistor include P-type field-effect transistors and/or have bodies shorted to the current flow path therethrough.
